(19) United States
(12) Patent Application Publication
(10) Pub. No.: US 2026/0148790 A1
(43) Pub. Date: May 28, 2026

(54) DETECTION AND COMPENSATION OF TIMING MARGIN ERRORS IN MEMORY

(71) Applicant: QUALCOMM Incorporated, San Diego, CA (US)

(72) Inventors: Darshan Kumar NANDANWAR, Bangalore (IN); Ankit GOSALIA, Milpitas, CA (US); Karimulla SYED, Bangalore (IN); Rohit CHAUREY, Fremont, CA (US); Kambhampati KRISHNAPRIYA, Bangalore (IN)

(21) Appl. No.: 19/225,891

(22) Filed: Jun. 2, 2025

Related U.S. Application Data
(63) Continuation of application No. 18/959,239, filed on Nov. 25, 2024.

(51) Int. Cl. G11C 29/12

(52) U.S. Cl. CPC G11C 29/12015; G11C 29/12005; G11C 2029/1204

(57) ABSTRACT

The present disclosure is directed to a method for operating a memory. The method includes sensing a bit line signal for a bit line of the memory transitioning between a first state and a second state when data is read from one or more memory cells of the memory or when data is written to the one or more memory cells of the memory. The method includes detecting a timing margin error in the memory based, at least in part, on a delay associated with the bit line signal transitioning between the first state and the second state. The method includes adjusting a parameter associated with the memory to compensate for the timing margin error.

### CROSS-REFERENCE TO RELATED APPLICATION(S)

This present application is a continuation of U.S. patent application Ser. No. 18/959,239, filed Nov. 25, 2024, which is hereby incorporated by reference herein.

### TECHNICAL FIELD

Aspects of the present disclosure generally relate to a memory (e.g., level 1 cache) and, more particularly, to techniques for detecting a timing margin error in the memory and adjusting a parameter associated with the memory to compensate for the timing margin error.

### BACKGROUND

A CPU may include a processing unit (e.g., a core) that includes local memory, such as level 1 cache. The local memory may include a memory array that includes a plurality of memory cells. For instance, the memory cells may include static random access memory (SRAM) cells. The SRAM cells may include multiple transistors, such as 6 transistors, and may be referred to as 6T SRAM cells. Over time, the transistors included in SRAM cells may age and may degrade performance of the memory. For instance, aging of the transistors in SRAM cells used in the memory may adversely affect timing margins specifying time constraints for read/write operations of the memory, which may cause the memory to generate faults or fail.

### BRIEF SUMMARY

In one aspect, a method for operating a memory is provided. The method includes: sensing a bit line signal for a bit line of the memory transitioning between a first state and a second state when data is read from one or more memory cells of the memory or when data is written to the one or more memory cells of the memory; detecting a timing margin error in the memory based, at least in part, on a delay associated with the bit line signal transitioning between the first state and the second state; and adjusting a parameter associated with the memory to compensate for the timing margin error.

In another aspect, a timing margin monitor for detecting timing margin errors in a memory array is provided. The timing margin monitor includes: a transition detector having an input coupled to a bit line of the memory array, the transition detector configured to output a pulse signal having a width corresponding to a delay associated with a bit line signal on the bit line transitioning between a first logic state and a second logic state; a pulse detector configured to generate a sensed voltage signal based on the pulse signal, the sensed voltage signal having a voltage value corresponding to the width of the pulse signal; and a comparator configured to determine whether a timing margin error exists in the memory array based on the sensed voltage signal and a reference voltage signal.

In yet another aspect, an apparatus is provided. The apparatus includes: means for sensing a bit line signal for a bit line of a memory transitioning between a first state and a second state when data is read from one or more memory cells of the memory or when data is written to the one or more memory cells of the memory; means for detecting a timing margin error in the local memory based, at least in part, on a delay associated with the bit line signal transitioning between the first state and the second state; and means for adjusting a parameter associated with the memory to compensate for the timing margin error.

The following description and the related drawings set forth in detail certain illustrative features of one or more aspects.

### BRIEF DESCRIPTION OF THE DRAWINGS

The appended figures depict certain features of one or more aspects of the present disclosure and are therefore not to be considered limiting of the scope of this disclosure.

FIG. 1 depicts a block diagram of a CPU cluster according to some aspects of the present disclosure.

FIG. 2 depicts components of a memory array according to some aspects of the present disclosure.

FIG. 3 depicts a block diagram of components of a system for detecting and compensating for a timing margin error in a memory array according to some aspects of the present disclosure.

FIG. 4 depicts a block diagram of components of a timing margin monitor for a memory array according to some aspects of the present disclosure.

FIG. 5 depicts a logic circuit for a transition detector of a timing margin monitor for a memory array according to some aspects of the present disclosure.

FIG. 6 depicts a logic circuit for a pulse detector of a timing margin monitor for a memory array according to some aspects of the present disclosure.

FIG. 7 depicts a logic circuit for a comparator of a timing margin monitor for a memory array according to some aspects of the present disclosure.

FIG. 8 depicts a state diagram for a finite state machine of a timing margin monitor for a memory array according to some aspects of the present disclosure.

FIG. 9 depicts a block diagram of a timing margin controller according to some aspects of the present disclosure.

FIG. 10 depicts a first scheme to compensate for a timing margin error in a memory array according to some aspects of the present disclosure.

FIG. 11 depicts a second scheme to compensate for a timing margin error in a memory array according to some aspects of the present disclosure.

FIG. 12 depicts a sequence diagram for compensating for a timing margin error in a memory array according to some aspects of the present disclosure.

FIG. 13 depicts a flowchart of a method for detecting aging of memory in a CPU according to some aspects of the present disclosure.

FIG. 14 depicts an example processing system in which the system of FIG. 3 may be included according to various aspects of the present disclosure.

To facilitate understanding, identical reference numerals have been used, where possible, to designate identical elements that are common to the drawings. It is contemplated that elements and features of one aspect may be beneficially incorporated in other aspects without further recitation.

### DETAILED DESCRIPTION

Aspects of the present disclosure provide techniques and systems for detecting a timing margin error in a memory (e.g., memory array including static random access (SRAM) memory cells) and automatically compensating for the timing margin error.

The performance of systems-on-a-chip (SoCs) and complementary metal-oxide semiconductor (CMOS) circuits' is sensitive to parametric variations, such as power-supply voltage and temperature (PVT) and aging effects (e.g., PVT and aging-PVTA). The aging of CMOS circuits is typically caused by the following effects: bias temperature instability (BTI), hot-carrier injection (HCI), electromigration (EM), and time dependent dielectric breakdown (TDDB). The most relevant aging effect is the BTI, namely the negative bias temperature instability (NBTI), which affects p-channel metal oxide field effect transistors (pMOSFETs), and the positive bias temperature instability (PBTI), which affects n-channel metal oxide field effect transistors (nMOSFETs). These effects (e.g., NBTI and PBTI) degrade digital circuits' performance over time, which increases variability in CMOS circuits. The degradation in performance due to these aging effects leads to decreased switching speeds, eroding timing margins (e.g., in memory arrays) and, in some instances, delay faults and even chip failures.

CPU static random access memory (SRAM) caches are dense and are often used in performance critical applications, such as in high-frequency CPU-cores. When used in these performance critical applications, CPU SRAMs must accommodate high switching speeds and, as a result of the high switching speeds, the effects of NBTI and PBTI adversely affect the memory timing margin of the CPU SRAMs. Existing techniques compensate for these aging effects by implementing memory timing adjustment logic (e.g., called dynamic MEMACC) to adjust the memory read/write timing cycles.

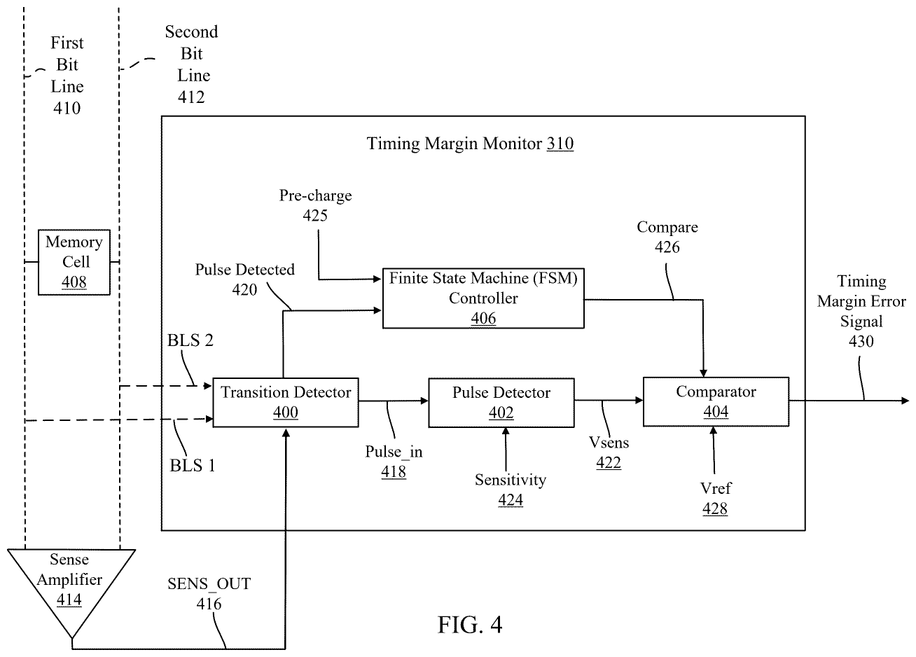

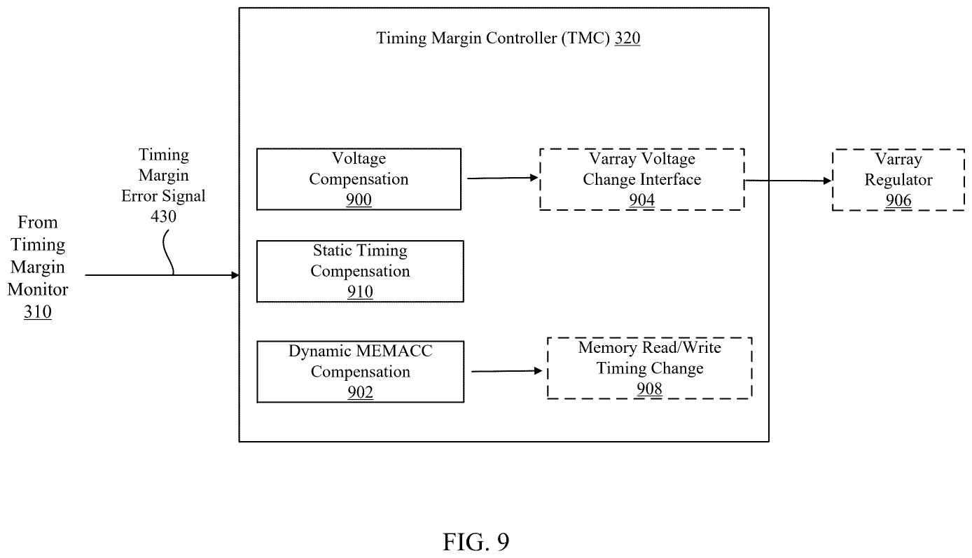

Example aspects of the present disclosure are directed to techniques for detecting a timing margin error (or imminence of such an error) in a memory array (e.g., including SRAM cells) implemented in a memory (e.g., level 1 cache). For instance, as will be discussed with reference to FIG. 4, the disclosed techniques may include a timing margin monitor that detects the timing margin error (or imminence of such an error) and asserts the timing margin error to a timing margin controller, which will be discussed with reference to FIGS. 9-11. The timing margin controller may be configured to implement dynamic compensation schemes (e.g., voltage compensation or memory access timing compensation) to compensate for the timing margin error (or imminence of such an error). The dynamic compensation schemes may include initially adjusting a parameter (e.g., voltage or memory access timing) associated with the memory array to a pessimistic value (e.g, optimal or target value) and, assuming adjusting the parameter to the pessimistic value compensates for the detected timing margin error, may further include incrementally adjusting the parameter to decrease the parameter value (e.g., from pessimistic value to a less pessimistic value) to determine the minimum adjustment to the parameter to compensate for the timing margin error. In this manner, the disclosed techniques provide for early detecting of timing margin errors and compensating for such errors in a more energy-efficient manner compared to existing techniques for compensating for such timing margin errors.

### Example CPU Cluster

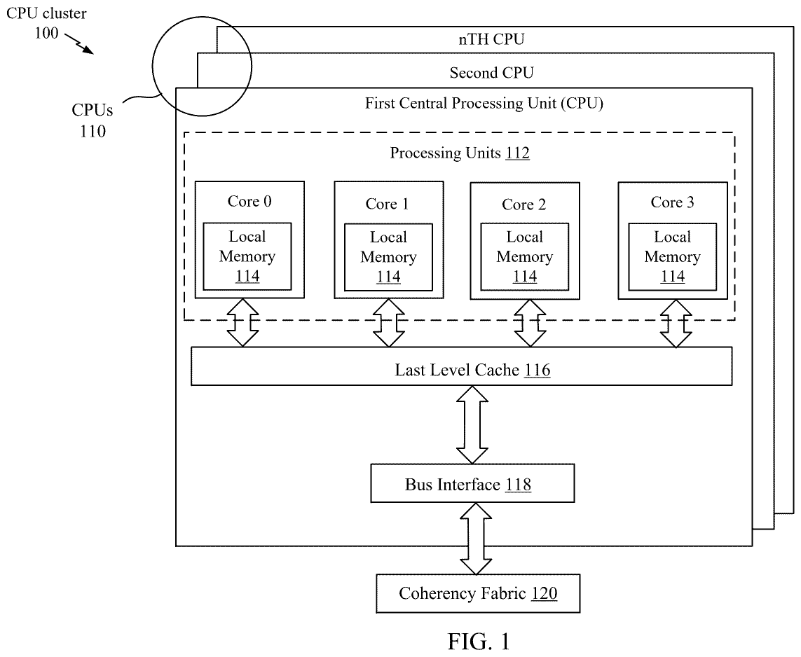

FIG. 1 depicts a block diagram of a CPU cluster 100 according to some aspects of the present disclosure. The CPU cluster 100 may include a plurality of CPUs 110. Each of the CPUs 110 may include a plurality of processing units 112. For example, as illustrated, each of the CPUs 110 may include four separate processing units 112 (e.g., labeled as Core 0, Core 1, Core 2, and Core 3). It should be appreciated that the scope of the present disclosure is not intended to be limited to CPUs have four separate processing units 112 and therefore may include CPUs having more or fewer processing units 112.

As illustrated, each of the processing units 112 may include a local memory 114 (e.g., level 1 cache). The local memory 114 is the most efficient (e.g., closest and fastest) memory source for the respective processing core 112. The local memory 114 may store data and instructions frequently accessed. By storing such data and instructions in the local memory 114, the respective processing unit 112 may access such data and instructions without having to access higher level memory (e.g., main memory).

Each of the CPUs 110 may include a last level cache 116 (e.g., referred to as level 3 cache). The last level cache 116 has a much larger storage capacity compared to the local memory 114 (e.g., level 1 cache) of each respective processing unit 112. As a result, the last level cache 116 may be shared amongst the plurality of processing units 112. Also, as the name suggests, the last level cache 116 represents the final cache before the respective CPU 110 accesses the main memory.

Each of the CPUS 110 may include a bus interface 118. The bus interface 118 may be a physical (and logical) interface that connects a respective CPU to other components. For example, the bus interface 118 may connect the respective CPU to a coherency fabric 120 (e.g., system bus) that connects the respective CPU to other CPUs included in the CPU cluster 100 as well as other components, such as main memory.

### Example Memory Array

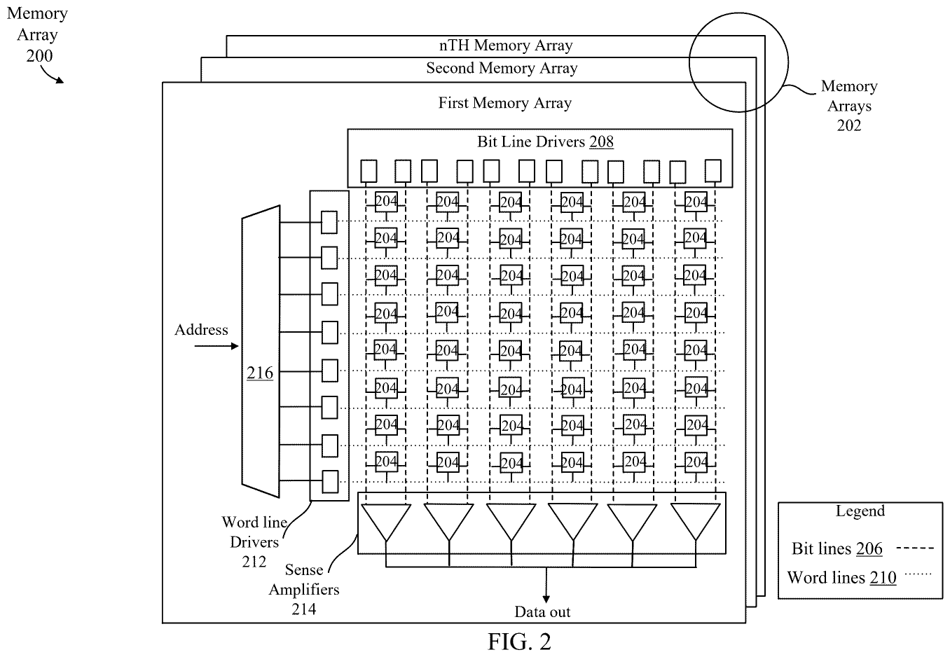

FIG. 2 depicts a memory array 200 according to some aspects of the present disclosure. The memory array 200 may be implemented as the local memory 114 (e.g., level 1 cache) discussed above with reference to the CPU cluster 100 of FIG. 1.

In some aspects, the memory array 200 may include a plurality of memory arrays 202 (e.g., first memory array, second memory array, nTH memory array). As illustrated, in some aspects, each of the memory arrays 202 may include a plurality of memory cells 204, a plurality of bit lines 206, a plurality of bit line drivers 208, a plurality of word lines 210, a plurality of word line drivers 212, a plurality of sense amplifier 214, and an address demultiplexer 216.

In some aspects, the memory cells 204 may be arranged in a row-column configuration. For example, the memory cells 204 of the first memory array in FIG. 2 are arranged as 8 rows and 6 columns. The memory cells 204 in each column are coupled to two respective bit lines of the plurality of bit lines 206. Furthermore, the memory cells 204 in each row are coupled to a respective word line of the plurality of word lines 210.

In some aspects, the address demultiplexer 216 may receive an address (e.g., typically a combination of row and column addresses) from a memory controller (not shown). The address demultiplexer 216 may separate the address into a row address (e.g., corresponding to one of the rows of memory cells 204) and a column address (e.g., corresponding to one of the columns of memory cells 204). In some aspects, the address demultiplexer 216 may output the row and column addresses separately to the appropriate circuits (e.g., bit line drivers 208, word line driver 212) of the memory array 202. In this manner, the appropriate bit lines 206 (e.g., two bit lines associated with the column in which the memory cell to be accessed is included) and word line 210 may be selected to access a particular memory cell of the plurality of memory cells 204. For instance, the particular memory cell may be accessed to perform a read operation in which data stored on the particular memory cell is read or a write operation in which data is written to the particular memory cell.

Each respective sense amplifier of the plurality of sense amplifiers 214 may be connected to a respective pair of bit lines 206 that is connected to memory cells 204 included in a respective column of the plurality of columns of memory cells 204. The respective pair of bit lines may include a true bit line and a complement bit line. The true bit line may carry a true (or normal) logic level of data being read from (or written to) a respective memory cell of the memory cells 204 connected to the true bit line, whereas the complement bit line may carry the complement (or inverted) logic level of the data.

When the respective memory cell is accessed during a memory operation (e.g, read operation or write operation), the sense amplifier 214 connected to the respective pair of bit lines 206 (that is, the true bit line and the complement bit line) may sense a voltage difference (e.g., in the range of millivolts or smaller) between the true bit line and the complement bit line. The sense amplifier 214 may amplify the voltage difference to a full logic level (e.g., low or high) that can be reliably interpreted. In some aspects, the sense amplifier 214 outputs a signal indicative of a state (e.g., 0 or 1) of the respective memory cell accessed during a read operation.

In some aspects, each of the memory cells 204 may be a static random access memory (SRAM) cell. For instance, the SRAM cell may include 6 transistors and therefore may be referred to as 6T SRAM cells. The six transistors may include two pull-up transistors and two pull-down transistors that collectively form two cross-coupled inverters responsible for storing a state (e.g., logic 1 or logic 0) of the SRAM cell. The six transistors may also include two access transistors that connect the SRAM cell to two bit lines 206 of the respective memory array 202. More specifically, the source and drain terminals of the two access transistors connect to two bit lines 206 corresponding to the column in which the SRAM cell is located. Additionally, the gate terminal of the two access transistors is connected to the word line 210 corresponding to the row in which the SRAM cell is located.

Over time, one or more of the transistors included in the 6T SRAM cell may, as discussed above, age due to NBTI and PBTI. For example, the effects of PBTI on the PMOS transistors included in the 6T SRAM cell may cause a threshold voltage of the PMOS transistors to increase, making the PMOS transistors more difficult to turn on. This shift in the threshold voltage can lead to reduced drive current and slower switching speeds, which can negatively affect the performance of the memory array 200 in which the 6T SRAM cell is used. For example, the timing margin of the memory array 200 that specifies time constraints under which memory operations (e.g., read, write) are to be executed to prevent data loss or errors may erode, which may cause the memory array 200 to experience faults or, in some cases, fail.

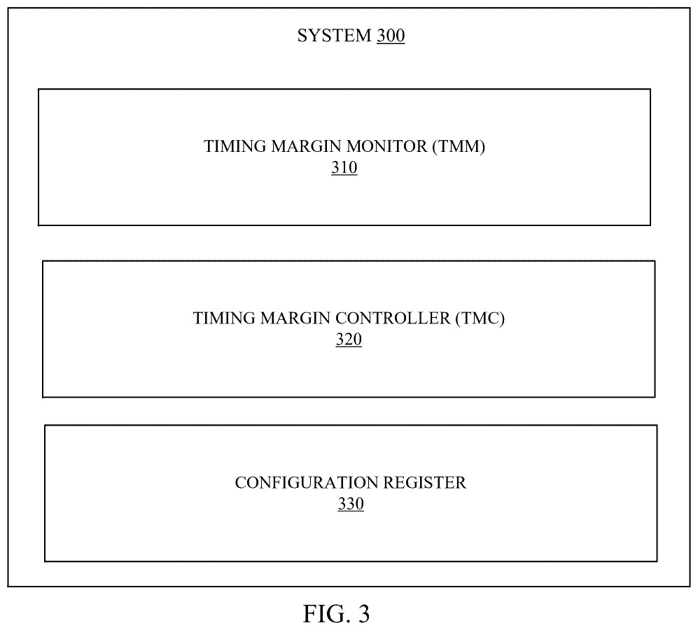

As will now be discussed with reference to FIG. 3, the present disclosure is directed to a system for monitoring a memory array (e.g., including 6T SRAM cells) for a timing margin error and for proactively compensating for the timing margin error by, for example, auto-optimizing memory timing adjustment logic (e.g., MEMACC settings) to improve performance (e.g., reliability) of the memory array.

### Example System for Detection and Compensation of Timing Margin Errors in Memory Cells

FIG. 3 depicts a block diagram of components of a system 300 for detecting timing margin errors (or imminence of such errors) in memory cells (e.g., 6T SRAM cells) and automatically compensating for the detected timing margin errors according to some aspects of the present disclosure.

The system 300 may include one or more timing margin monitors (TMMs) 310 and a timing margin controller (TMC) 320. The TMM 310 may be implemented in a memory array, such as the memory array 200 discussed above with reference to FIG. 2, that, in some aspects, may be implemented as local memory (e.g., level 1 cache) of a processing unit included in a respective CPU of a CPU cluster (e.g., the CPU cluster 100 in FIG. 1). For instance, the TMM 310 may be coupled to a set of bit lines in the memory array (e.g., two of the bit lines 206 in the memory array 200 of FIG. 2). As will be discussed in more detail with reference to FIGS. 4-8, the TMM 310 may be configured to proactively monitor delays in transitions of bit line signals when a memory cell (e.g., 6T SRAM) coupled to the set of bit lines is accessed (e.g., during a read operation or write operation). When the TMM 310 detects a delay in transitions on the set of bit lines that indicates the memory cell has aged, the TMM 310 may output a signal to the TMC 320, which may be implemented in logic for a memory controller (e.g., cache controller) that controls operation of the memory array (e.g., level 1 cache). As will be discussed in more detail with reference to FIGS. 9-12, the TMC 320 may implement one of multiple compensation schemes (e.g., voltage, static timing, dynamic MEMACC) to mitigate the delay in the transition of the bit line signals when the aging memory cell is accessed and, as a result, may improve performance of the memory array.

In some aspects, the system 300 may include a configuration register 330. The configuration register 330 may be implemented in the logic for the memory controller (e.g., the cache controller) that controls operation of the memory array (e.g., level 1 cache). In some aspects, the configuration register 330 may be programmed to indicate which of the multiple compensation schemes the TMC 320 may implement to compensate for the timing margin error detected by the TMM 310.

### Example Timing Margin Monitor

FIG. 4 depicts components of the TMM 310 according to some embodiments of the present disclosure. The TMM 310 may include a transition detector 400, a pulse detector 402, a comparator 404, and a finite state machine (FSM) controller 406.

As illustrated, a memory cell 408 (e.g., a 6T SRAM cell) may be connected to a first bit line 410 and a second bit line 412. A sense amplifier 414 (e.g., one of the sense amplifiers 214 of FIG. 2) may also be connected to the first bit line 410 and the second bit line 412. In this manner, the sense amplifier 414 may receive, as inputs, a first bit line signal BLS 1 (e.g, a voltage signal) associated with the first bit line 410 and a second bit line signal BLS 2 (e.g., also a voltage signal) associated with the second bit line 412.

When the memory cell 408 is accessed during a memory operation (e.g., read operation or write operation), the sense amplifier 414 may, based on the first bit line signal BLS 1 and the second bit line signal BLS 2, detect a voltage differential (e.g., in the range of millivolts or smaller) between the first bit line 410 and the second bit line 412. The sense amplifier 414 may amplify the voltage differential to a full logic level (e.g., first state or second state) and, in some aspects, may provide the full logic level as an output signal 416 (e.g., labeled as SENS_OUT).

The transition detector 400 may be configured to detect transitions (e.g., from a first (or low) state to a second (or high) state and vice versa) in at least one of the first bit line signal BLS 1 and the second bit line signal BLS 2 when the memory cell 408 (e.g., 6T SRAM cell) connected to the first bit line 410 and the second bit line 412 is accessed during the memory operation (e.g., read operation or write operation). As the memory cell 408 ages (or when PVTA degradation occurs), the bit lines (e.g., first bit line 410 and second bit line 412) may take longer to transition from the first (or low) state to the second (or high) state and vice versa.

In some aspects, the transition detector 400 may receive one or more bit line signals as inputs. For instance, the transition detector 400 may receive the first bit line signal BLS 1, the second bit line signal BLS 2, or both. Furthermore, in some aspects, the transition detector 400 may receive the output signal 416 generated by the sense amplifier 414. Based on the received inputs, the transition detector 400 may detect a delay associated with the one or more bit line signals (e.g., BLS 1, BLS 2, or both) transitioning between states and, in response to detecting the delay, may output a pulse signal 418 (e.g., labeled Pulse_in). The pulse signal 418 may have a width that is proportional to the detected delay and, in some aspects, may be provided as an input to the pulse detector 402. In some aspects, the transition detector 400 may also generate an interrupt signal 420 (e.g., labeled Pulse Detected) that is provided as an input to the FSM controller 406.

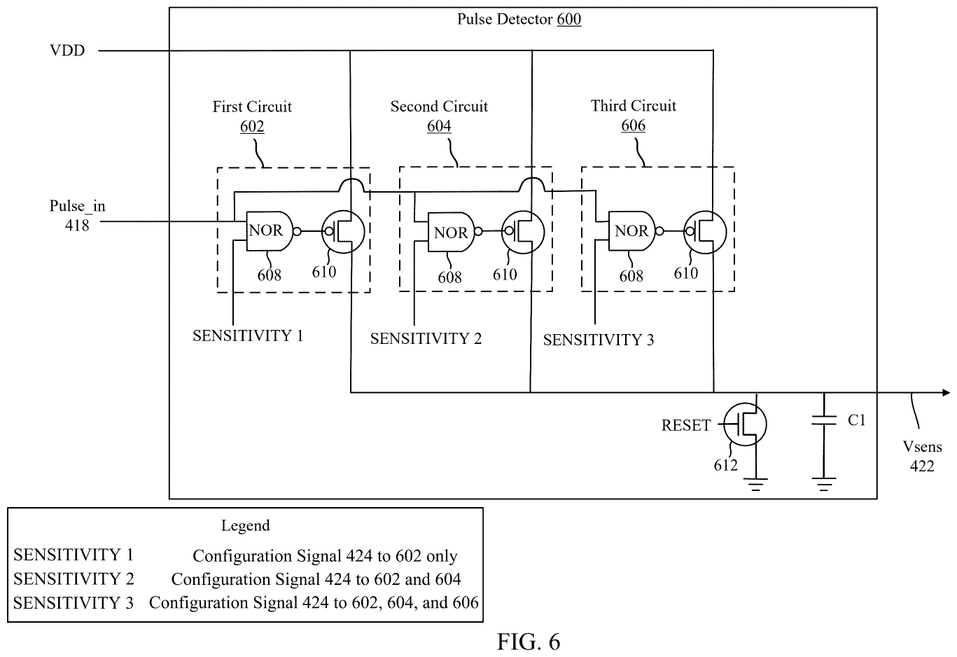

The pulse detector 402 may be configured to output a sensed voltage signal 422 (e.g., labeled Vsens) based on the pulse signal 418 received from the transition detector 400. In some aspects, the sensed voltage signal 422 may be indicative of a direct current (DC) voltage value that is proportional to the width of the pulse (e.g., the pulse signal 418) detected by the transition detector 400 and indicative of a transition on one of the bit lines 410, 412. As will be discussed in FIG. 6, the pulse detector 402 may include a capacitor that is charged to the DC voltage value.

In some aspects, the sensitivity of the pulse detector 402 may be configurable. For example, a configuration signal 424 (e.g., labeled Sensitivity) may be provided as an input to the pulse detector 402. As will be discussed in more detail with reference to FIG. 6, the configuration signal 424 may be provided to different circuits of the pulse detector 402 to configure the sensitivity of the pulse detector 402. For example, the sensitivity of the pulse detector 402 may be configured based on operating conditions of the memory (e.g., the memory array 200 in FIG. 2) the TMM 310 is monitoring. As another example, the pulse detector 402 may be calibrated by, at least in part, adjusting the sensitivity of the pulse detector 402.

The FSM controller 406 may configurable in a plurality of different states. For instance, in some aspects, the FSM controller 406 may have three states: Reset, Sample, and Compare. In other aspects, the FSM controller 406 may have more or fewer states.

When the FSM controller 406 receives a reset signal 425 (e.g., labeled Pre-Charge), the FSM controller 406 may enter the Reset state. In the Reset state, all operations of the TMM 310 may be reset to an initial state. For example, in the Reset state, all values (e.g., in the capacitor of the pulse detector 402) may be discharged and restored to values associated with an intended operating state (e.g., correct) of the TMM 310. In some aspects, these operations associated with the Reset state may be executed during a single clock cycle.

The FSM controller 406 may generally be in the Sample state. In the Sample state, the FSM controller 406 waits for the transition detector 400 to detect a transition on one of the bit lines 410, 412 during a memory operation (e.g., read or write) involving the memory cell 408 and, in response to detecting the transition, generate the pulse signal 418 that is provided as an input to the pulse detector 402 and the interrupt signal 420 that is provided as an input to the FSM controller 406. Upon receiving the interrupt signal 420, the FSM controller 406 may enter the Compare state.

When the FSM controller 406 enters the Compare state, the FSM controller 406 may output a compare signal 426 (e.g., labeled Compare) to the comparator 404. The compare signal 426 may activate the comparator 404 to compare the voltage signal 422 to a reference voltage signal 428 indicative of a reference voltage, Vref, generated by a reference voltage generation circuit configured to age (e.g., due to PVTA) faster than the memory cell 408. In this manner, the sensitivity of the TMM 310 may be higher when the PVTA conditions are worse.

In some aspects, the reference voltage generation circuit may include a transistor (e.g., a NMOS transistor) and a capacitor. A gate of the transistor may be coupled to a supply voltage rail, Vdd, and a drain of the transistor may be coupled to the capacitor. Furthermore, the reference voltage, Vref, generated by the reference voltage generation circuit may be controlled by a threshold voltage, Vth of the transistor. For instance, the transistor may always be operating in a stress-mode and, due to operating in the stress mode, may charge the capacitor to a DC voltage value corresponding to the reference voltage, Vref. In some aspects, the reference voltage, Vref, generated by the reference voltage generation circuit may be represented by the following formula:

$$V ref = V dd - V th$$

The comparator 404 may be configured to output a timing margin error signal 430 based on the comparison of the voltage signal 422 and the reference voltage signal 428. For instance, the comparator 404 may be configured to output the timing margin error signal 430 when the sensed voltage, Vsens, indicated by the sensed voltage signal 422 output by the pulse detector 402 is higher than the reference voltage, Vref, indicated by the reference voltage signal 428 output by the reference voltage generation circuit. In some aspects, the comparator 404 may determine the sensed voltage, Vsens, is higher than the reference voltage, Vref, by determining a DC voltage value stored in the capacitor of the pulse detector 402 and indicative of the sensed voltage is greater than a DC voltage value stored in the capacitor of the reference voltage generation circuit and indicative of the reference voltage.

### Example Transition Detector

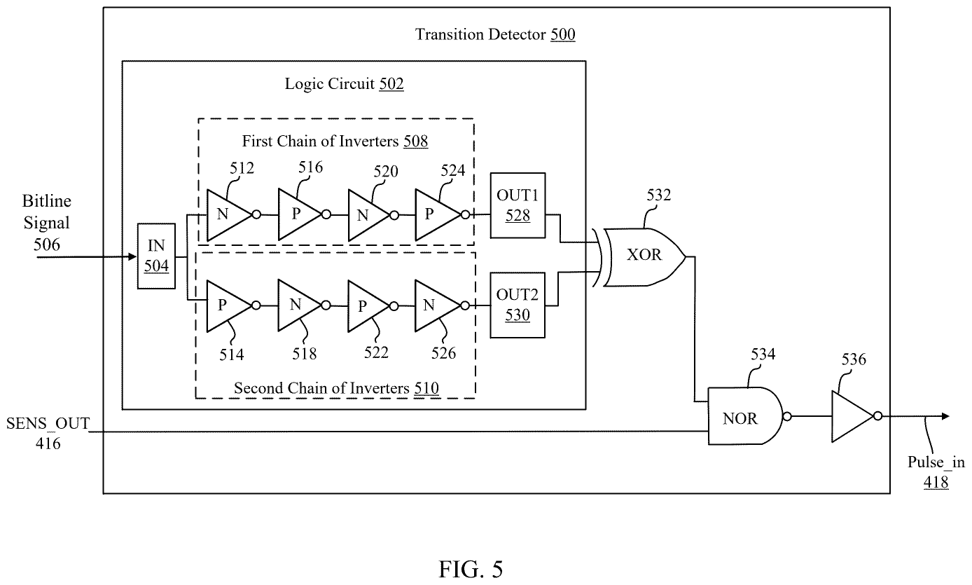

FIG. 5 depicts an example transition detector 500 according to some aspects of the present disclosure. The transition detector 500 represents one example of the transition detector 400 included in the TMM 310 discussed above with reference to FIG. 4. However, the scope of the present disclosure is not intended to be limited to TMMs 310 having the transition detector 500 of FIG. 5.

The transition detector 500 may include a logic circuit 502. The logic circuit 502 may have an input 504 coupled to a bit line (e.g., the first bit line 410 of FIG. 4 or the second bit line 412 of FIG. 4). In this manner, the logic circuit 502 may receive a bit line signal 506 (e.g., the first bit line signal BLS 1 of FIG. 4 or the second bit line signal BLS 2 of FIG. 4) at the input 504 of the logic circuit 502.

In some aspects, the logic circuit 502 may include a first chain of inverters 508 and a second chain of inverters 510. As illustrated, in some aspects, the first chain of inverters 508 and the second chain of inverters 510 may include a first inverter 512, 514, a second inverter 516, 518, a third inverter 520, 522, and a fourth inverter 524, 526. In other aspects, the first chain of inverters 508 and the second chain of inverters 510 may include more or fewer inverters.

The input of the first inverter 512 in the first chain of inverters 508 and the input of the first inverter 514 in the second chain of inverters 510 may each be connected to the input 504 of the logic circuit 502. In this manner, the first inverter 512 of the first chain of inverters 508 and the first inverter 514 of the second chain of inverters 510 may each receive the bit line signal 506.

The input of the second inverter 516 in the first chain of inverters 508 may be connected to the output of the first inverter 512 in the first chain of inverters 508, and the input of the second inverter 518 in the second chain of inverters 510 may be connected to the output of the first inverter 514 in the second chain of inverters 510.

The input of the third inverter 520 in the first chain of inverters 508 may be connected to the output of the second inverter 516 in the first chain of inverters 508, and the input of the third inverter 522 in the second chain of inverters 510 may be connected to the output of the second inverter 518 in the second chain of inverters 510.

The input of the fourth inverter 524 in the first chain of inverters 508 may be connected to the output of the third inverter 520 in the first chain of inverters 508, and the input of the fourth inverter 526 in the second chain of inverters 510 may be connected to the output of the third inverter 522 in the second chain of inverters 510.

In some aspects, the inverters 512, 516, 520, 524 in the first chain of inverters 508 may alternate between n-type inverters and p-type inverters. For instance, the first inverter 512 may be an n-type inverter (e.g., denoted by N), the second inverter 516 may be a p-type inverter (e.g., denoted by P), the third inverter 520 may be an n-type inverter, and the fourth inverter 524 may be a p-type inverter.

In some aspects, the inverters 514, 518, 522, 526 in the second chain of inverters 510 may alternate between p-type inverters and n-type inverters. For instance, the first inverter 514 may be a p-type inverter (e.g., denoted by N), the second inverter 518 may be an n-type inverter (e.g., denoted by P), the third inverter 522 may be a p-type inverter, and the fourth inverter 526 may be an n-type inverter.

As illustrated, the logic circuit 502 may include a first output 528 (e.g., labeled OUT1) and a second output 530 (e.g., labeled OUT2). More specifically, the first output 528 may correspond to the output of the fourth inverter 524 in the first chain of inverters 508, and the second output 530 may correspond to the output of the fourth inverter 526 in the second chain of inverters 510.

In some aspects, the transition detector 500 may include a first logic gate 532. The outputs (e.g., first output 528, second output 530) of the logic circuit 502 that are provided as inputs to the first logic gate 532 may be either a first logic level (e.g., 1) or a second logic level (e.g., 0), and the first logic gate 532 may function as an exclusive OR gate (e.g., denoted by XOR). When the outputs of the logic circuit 502 are at different logic levels (e.g., OUT 1 at 1 and OUT 2 at 0 or vice versa), the output of the first logic gate 532 may be the first logic level (e.g., 1). Alternatively, the output of the first logic gate 532 may be the second logic level (e.g., 0) when the outputs of the logic circuit 502 are both at the same logic level (e.g., OUT 1 and OUT 2 are both 0 or OUT1 and OUT2 are both 1).

In some aspects, the transition detector 500 may include a second logic gate 534. The second logic gate 534 may receive the output of the first logic gate 532 as a first input and the output signal 416 (e.g., labeled SENS_OUT) from a sense amplifier (e.g., the sense amplifier 414 of FIG. 4) as a second input. The second logic gate 534 may function as a NOR gate. When the inputs to the second logic gate 534 are both at the second logic level (e.g., 0), the output of the second logic gate 534 may be the first logic level (e.g., 1). Alternatively, the output of second logic gate 534 may be the second logic level (e.g., 0) when the inputs to the second logic gate 534 are different (e.g., not the same as one another).

In some aspects, the transition detector 500 may include an inverter 536. As illustrated, an input of the inverter 536 may be connected to the output of the second logic gate 534. In this manner, the inverter 536 may receive the output of the second logic gate 534 and may invert the output of the second logic gate 534 to output the pulse signal 418.

### Example Pulse Detector

FIG. 6 depicts an example pulse detector 600 according to some aspects of the present disclosure. The pulse detector 600 represents one example of the pulse detector 402 included in the TMM 310 discussed above with reference to FIG. 4. However, the scope of the present disclosure is not intended to be limited to TMMs 310 having the pulse detector 600 of FIG. 6.

The pulse detector 600 may include a first circuit 602, a second circuit 604, and a third circuit 606. The first circuit 602, the second circuit 604, and the third circuit 604 may each include a logic gate 608 (e.g., labeled NOR) and a transistor 610 coupled to an output of the logic gate 608. The pulse signal 418 may be provided as a first input to the logic gate 608. The second input to the logic gate 608 may be the configuration signal 424 (e.g., labeled Sensitivity) discussed above with reference to the pulse detector 402 of FIG. 4.

In some aspects, the sensitivity of the pulse detector 600 may be configurable. To configure the sensitivity of the pulse detector 600, the configuration signal 424 may be provided as a second input to the logic gate 608 of one or more of the first circuit 602, second circuit 604, and third circuit 606 to configure the pulse detector 600 in each of the different sensitivity settings. For instance, the configuration signal 424 may be provided to the logic gate 608 of the first circuit 602 only to configure the pulse detector 600 to have a first sensitivity (e.g., SENSITIVITY 1). The configuration signal 424 may be provided to the logic gate 608 of the first circuit 602 and the logic gate 608 of the second circuit 604 to configure the pulse detector 600 to have a second sensitivity (e.g., SENSITIVITY 2). The configuration signal 424 may be provided to the logic gate 608 of the first circuit 602, the logic gate 608 of the second circuit 604, and the logic gate 608 of the third circuit 606 to configure the pulse detector 600 to have a third sensitivity (e.g., SENSITIVITY 3).

In some aspects, the pulse detector 600 may include a capacitor C1 coupled to the transistor 610 included in each of the first circuit 602, the second circuit 604, and the third circuit 606. The capacitor C1 may be charged to the DC voltage value of the voltage signal 422 (e.g., labeled Vsens) output by the pulse detector 600. The DC voltage value may be proportional to the width of the pulse signal 418 that is provided as an input to the pulse detector 600.

In some aspects, the pulse detector 600 may include a transistor 612 that may be activated when the FSM controller (e.g., FSM controller 406 in FIG. 4) is in the Reset state. When the transistor 612 is activated, the capacitor C1 may be discharged. In this manner, the capacitor C1 may be drained such that the capacitor C1 can be charged again the next time the pulse signal 418 is provided as an input to the pulse detector 600.

### Example Comparator

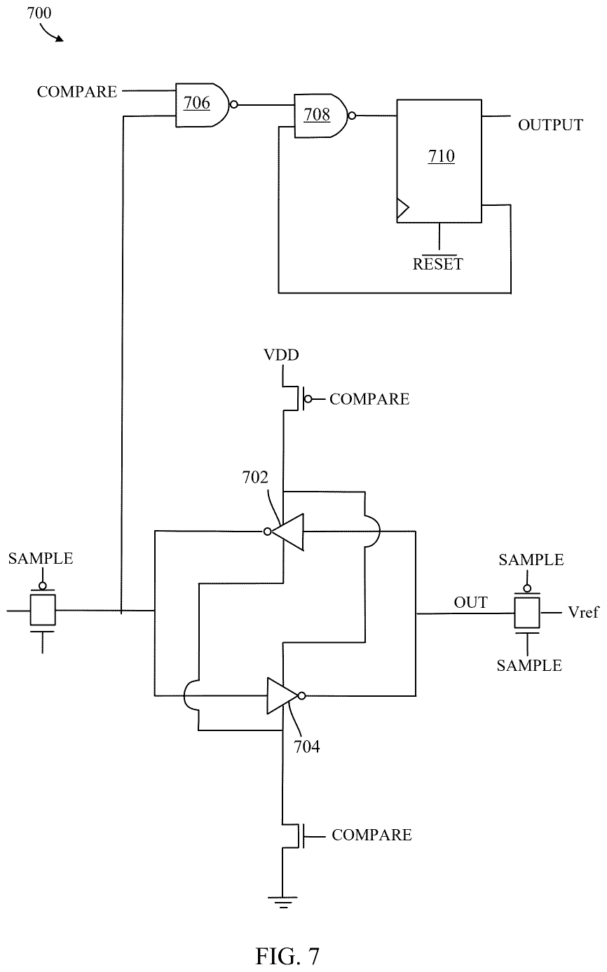

FIG. 7 depicts a comparator 700 according to some aspects of the present disclosure. The comparator 700 represents one example of the comparator 404 included in the TMM 310 discussed above with reference to FIG. 4. However, the scope of the present disclosure is not intended to be limited to TMMs 310 having the transition comparator 700 of FIG. 7.

The comparator 700 may include a first inverter 702, a second inverter 704 (e.g., cross coupled with first inverter 702), a first NAND gate 706, a second NAND gate 708, and a flip flop 710 connected as shown. The comparator 700 may be configured to amplify the differences between the sensed voltage (e.g., sensed voltage signal 422 output by pulse detector 402 of FIG. 4) and the reference voltage (e.g., reference voltage signal 428 generated by reference voltage generation circuit) triggering the voltage values to the extreme low/high voltages, VSS/VDD. In this manner, the sensed voltage and the reference voltage may be sampled through the transmission gates (e.g., activated by the compare signal 426 of FIG. 4) and these sampled voltages may be compared and amplified similar to how a sense amplifier (e.g., sense amplifier 214 of FIG. 2) does when reading a memory cell. In some aspects, this may be accomplished by providing the comparing signal (e.g., compare signal 426 of FIG. 4) causing the two cross-coupled inverters (e.g., first inverter 702, second inverter 704) to be activated (e.g., turned on).

By using the cross-coupled inverters to amplify the differences between the sensed voltage and the reference voltage that were sampled thorough the transmission gates, the comparator 700 may identify the weakest and strongest signal and may force the weakest signal to go to VSS and the strongest signal to VDD, thus remaining at each other's extreme value and generating a result.

The first NAND gate 706, the second NAND gate 708, and the flip-flop 710 may be used at the output of the comparator 700. By using these logic components at this particular location (e.g., at the output) of the comparator 700, a predictive error detection occurrence can be interpreted in the following clock cycles and corrective actions can take place. For instance, the OUTPUT of the flip-flop 710 may remain active at the output until a new memory operation (e.g., read or write) is detected and the flip-flop is reset to its initial state (e.g., by receiving the Reset signal 425 of FIG. 4).

### Example Diagram of Finite State Machine

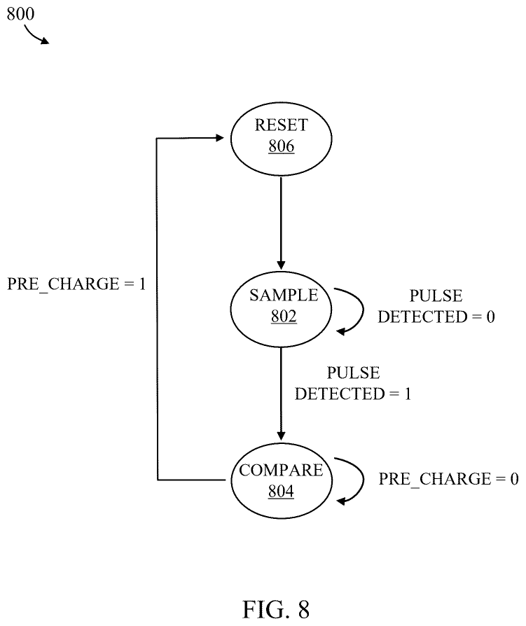

FIG. 8 depicts a state machine diagram 800 for a FSM controller of a TMM according to some aspects of the present disclosure. For example, the state machine diagram 800 may be for the FSM controller 406 of the TMM 310 discussed above with reference to FIG. 4.

The state diagram includes a sample state 802. The FSM controller may remain in the sample state 802 (or transition to a compare state 804) based on a value of an auxiliary variable (e.g., PULSE detected). For instance, the FSM controller may remain in the sample state 802 as long as the auxiliary variable has a first value (e.g., logic 0). The FSM controller may exit the sample state 802 to enter the compare state 804 when the value of the auxiliary variable switches from the first value to a second value (e.g., logic 1). For example, the auxiliary variable may transition from the first value to the second value when a new pulse is detected (e.g., by the transition detector 400 of FIG. 4) based on the one or more bit lines transitioning during a memory operation (e.g., read or write) involving a memory cell connected to the bit line(s). In some aspects, the auxiliary variable may correspond to the interrupt signal 420 that the transition detector 400 generates in response to detecting the transition on one or more of the bit lines 410, 412.

In some aspects, the FSM controller may remain in the compare state 804 until another memory operation is performed on the memory cell that causes the FSM controller to enter the sample state 802 (or a different memory cell connected to the one or more bit lines). Therefore, prior to the next memory operation, a pre-charge signal (e.g., labeled PRE_CHARGE) may trigger the initialization of the bit lines and may indicate that a new memory operation (e.g., read or write) will take place. Accordingly, the pre-charge signal may trigger the FSM controller to transition from the compare state 804 to a reset state 806 in which the TMM is prepared for the next memory operation. Otherwise, the FSM controller may remain in the compare state 804.

### Example Logic for Timing Margin Controller

FIG. 9 depicts a block diagram of components of the TMC 320 according to some aspects of the present disclosure. In some aspects, the TMC 320 may be implemented in a controller (e.g., cache controller) for memory (e.g., level 1 cache) being monitored by the TMM 310.

The TMC 320 may receive the timing margin error signal 430 from the TMM 310 indicating a timing margin error is present (or imminent). In response to receiving the timing margin error signal 430, the TMC 320 may be configured to compensate for the timing margin error going forward (e.g., in subsequent clock cycles). For example, the TMC 320 may be configured to implement voltage compensation 900 or dynamic MEMACC compensation 902.

To compensate for the timing margin error through voltage compensation 900, the TMC 320 may be configured to adjust (e.g., increase) a voltage at a power supply rail for the memory. In some aspects, the memory may, as discussed above, be local memory (e.g., memory array 200 of FIG. 2) of a processing unit included in a respective CPU of a CPU cluster, and the voltage adjustment may be determined based, at least in part, on a current PSTATE of the CPU. For instance, the TMC 320 may access one or more fuses of the CPU that are programmed with information, such as the target voltage and frequency settings for the current PSTATE of the CPU. The TMC 320 may then increase the voltage at the power supply rail to the target voltage for the PSTATE of the CPU.

In some aspects, the TMC 320 may include a voltage change interface 904 that allows the TMC 320 to communicate with a voltage regulator 906 for the memory. More specifically, the TMC 320 may send control signals associated with controlling operation of the voltage regulator 906 such that the voltage regulator 906 increases the voltage at the power supply rail to the target voltage.

In some aspects, increasing the voltage at the power supply rail for the memory to the target voltage value for the PSTATE of the CPU may compensate for the timing margin error and, as a result, the TMM 310 may stop outputting the timing margin error signal 430. Furthermore, in some aspects, the TMC 320 may decrease (e.g., in increments) the voltage value at the power supply rail until the TMM 310 starts outputting the timing margin error signal 430 again. In this manner, the TMC 320 may through voltage compensation 900 determine a minimum amount the voltage at the power supply rail needs to be increased to compensate for the timing margin error (or imminence of the timing margin error).

To compensate for the timing margin error through dynamic MEMACC compensation 902, the TMC 320 may be configured to adjust (e.g., increase) memory access compensation settings (e.g., access time). In some aspects, the memory may, as discussed above, be local memory (e.g., memory array 200 of FIG. 2) of a processing unit included in a respective CPU of a CPU cluster, and the voltage adjustment may be determined based, at least in part, on a PSTATE of the CPU. For instance, the TMC 320 may access one or more fuses of the CPU that are programmed with information, such as a target value for access time (e.g., maximum time it takes memory to provide requested data) of the memory given the PSTATE of the CPU. The TMC 320 may adjust (e.g., increase) the access time of the memory to the target value.

In some aspects, the TMC 320 may include memory read/write timing change 908 (e.g., software code) that interacts with a portion of the memory controller responsible for adjusting (e.g., increasing) the access time of the memory.

In some aspects, increasing the access time for the memory to the target value (e.g., maximum amount of time) may compensate for the timing margin error and, as a result, the TMM 310 may stop outputting the timing margin error signal 430. Furthermore, in some aspects, the TMC 320 may decrease (e.g., in increments) the access time until the TMM 310 starts outputting the timing margin error signal 430 again. In this manner, the TMC 320 may through dynamic MEMACC compensation 902 determine a minimum amount of time the access time of the memory needs to be increased to compensate for the timing margin error (or imminence of the timing margin error).

In some aspects, the TMC 320 may be configured to compensate for the timing margin error detected by the TMM 310 through static timing compensation 910. The static timing compensation 910 may be an alternative to the voltage compensation 900 and the dynamic MEMACC compensation 902 discussed above. With static timing compensation 910, the TMC 320 may be configured to adjust the access time for the memory. For instance, in some aspects, the TMC 320 may determine the target value for the access time for the memory based on the PSTATE of the CPU. But, in contrast the dynamic MEMACC compensation 902 discussed above, the static timing compensation 910 may not reduce the access time to find the minimum amount of time by which the access time for the memory needs to be increased to compensate for the timing margin error (or imminence of the timing margin error). In this manner, the static pessimistic timing compensation 910 may be considered an all-weather proof (e.g., one size fits all) solution that is generally less desirable than the voltage compensation 900 and the dynamic MEMACC compensation 902.

### Example Block Diagram of Timing Margin Controller Implementing Dynamic MEMACC Compensation for Timing Margin Errors

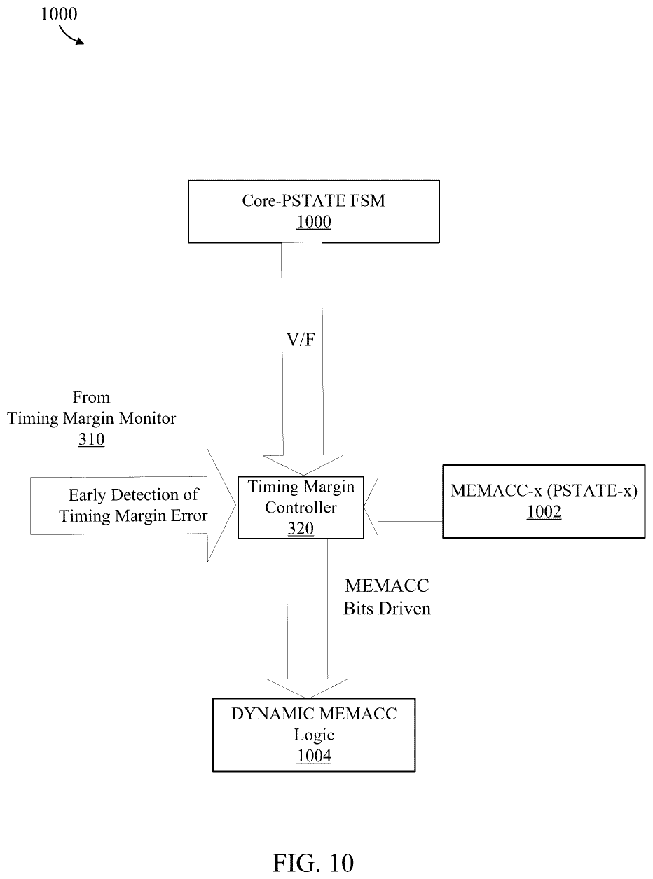

FIG. 10 depicts a block diagram of the TMC 320 implementing the dynamic MEMACC compensation 902 discussed above with reference to FIG. 9 according to some aspects of the present disclosure.

As illustrated, the TMC 320 may receive data (e.g., the timing margin error signal 430 of FIG. 4) indicating early detection of a timing margin error for memory. For instance, the memory may be a local memory (e.g., the memory array 200 of FIG. 2) for a processing unit of a respective CPU in a CPU cluster.

Upon receiving the data indicating early detection of the timing margin error, the TMC 320 may determine the PSTATE of the CPU. For instance, the TMC 320 may access a finite state machine 1000 to obtain voltage and/or frequency settings for each of the different PSTATEs in which the CPU may operate. More specifically, the TMC 320 may obtain the voltage and/or frequency settings for the current PSTATE of the CPU.

The TMC 320 may also obtain memory access timing settings for the memory based on the current PSTATE of the CPU. For example, the TMC 320 may obtain the memory access timing settings from another controller 1002 included in the respective CPU.

The TMC 320 may be configured to determine one or more adjustments to the memory access timing settings for the memory based on the voltage and/or frequency settings for the PSTATE of the CPU. Furthermore, the TMC 320 may be configured to communicate the adjustments to the memory access timing settings to dynamic MEMACC logic 1004 configured to apply the adjustments to the memory access timing settings to the memory.

In some aspects, the TMC 320 may be configured to optimize the memory access timing settings to find the minimum adjustments needed to compensate for the detected timing margin error (or imminence of the timing margin error). In this manner, by finding the minimum adjustments needed to the memory access timing settings, the TMC 320 may provide a solution for compensating for timing margin errors that is improved (e.g., more energy efficient) compared to static timing compensation schemes that do not perform multiple iterations of adjustments to the memory access timing settings to find the minimum adjustments needed to compensate for timing margin errors.

### Example Block Diagram of Timing Margin Controller Implementing Voltage Compensation for Timing Margin Errors

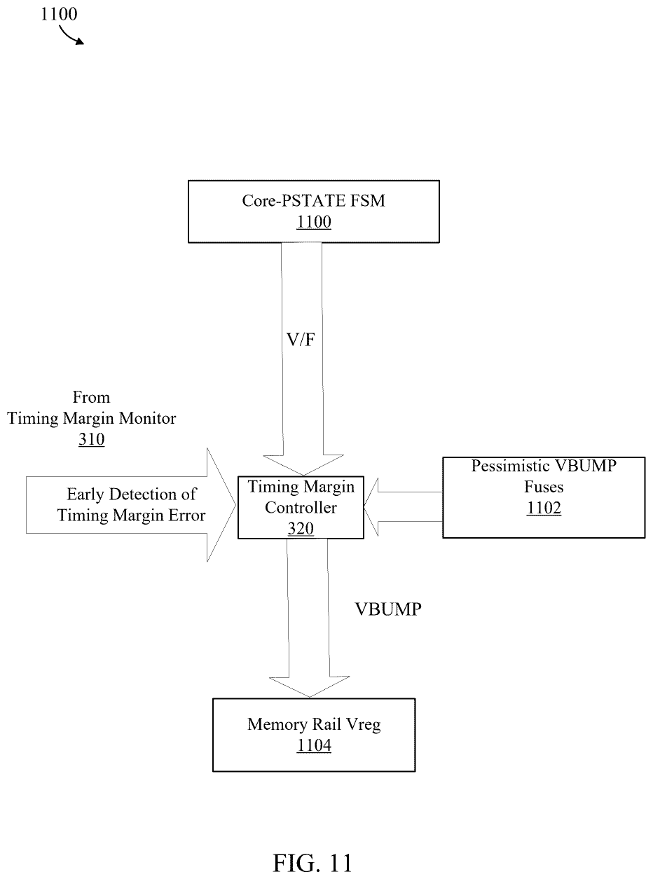

FIG. 11 depicts a block diagram of the TMC 320 implementing the voltage compensation 900 discussed above with reference to FIG. 9 according to some aspects of the present disclosure.

As illustrated, the TMC 320 may receive data (e.g., the timing margin error signal 430 of FIG. 4) indicating early detection of a timing margin error for memory. For instance, the memory may be a local memory (e.g., the memory array 200 of FIG. 2) for a processing unit of a respective CPU in a CPU cluster.

Upon receiving the data indicating early detection of the timing margin error, the TMC 320 may determine the PSTATE of the CPU. For instance, the TMC 320 may access a finite state machine 1100 to obtain voltage and/or frequency settings for each of the different PSTATEs in which the CPU may operate. More specifically, the TMC 320 may obtain the voltage and/or frequency settings for the current PSTATE of the CPU.

The TMC 320 may obtain target voltage values (e.g., maximum voltage values) for a power supply rail of the memory given the current PSTATE of the CPU. For example, the TMC 320 may access one or more fuses 1102 programmed with the target voltage values for the power supply rail of the memory given the current PSTATE of the CPU.

The TMC 320 may be configured to increase (e.g., bump) the voltage at the power supply rail for the memory to the target value. For example, the TMC 320 may provide one or more control signals to a voltage regulator 1104 of the CPU that is responsible for adjusting a voltage of the power supply rail.

In some aspects, the TMC 320 may be configured to optimize the voltage adjustment to the power supply rail of the memory to find the minimum adjustment needed to compensate for the detected timing margin error (or imminence of the timing margin error). In this manner, by finding the minimum adjustments needed to the voltage at the power supply rail for the memory, the TMC 320 may provide a solution for compensating for timing margin errors that is improved (e.g., more energy efficient) compared to static timing compensation schemes that do not perform multiple iterations of adjustments to the voltage at the power supply rail of the memory to find the minimum adjustments needed to compensate for timing margin errors.

### Example Sequence Diagram for Detecting Timing Margin Errors and Dynamically Compensating for the Timing Margin Errors

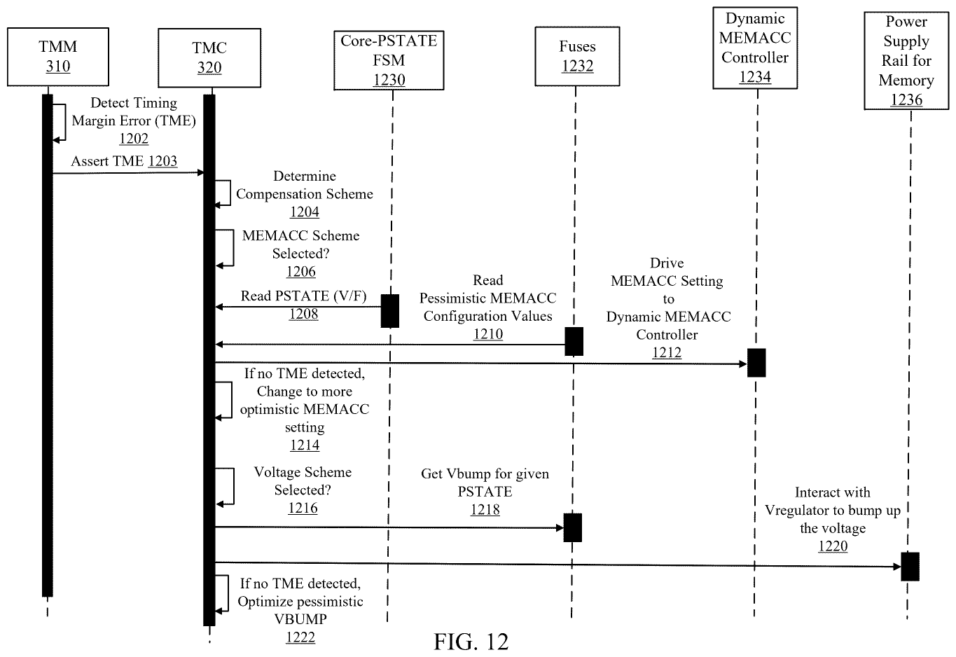

FIG. 12 depicts a sequence diagram for detecting and dynamically compensating for timing margin errors (or imminence of such errors) in memory according to some aspects of the present disclosure.

At 1202, the TMM 310 may detect a timing margin error (or imminence of such an error) in memory. For instance, at 1203, the TMM 310 may assert the timing margin error by outputting a timing margin error signal (e.g., the timing margin error signal 430 of FIG. 4) to the TMC 320 in response to detecting a delay associated with bit line signals transitioning between states (e.g., logic high and logic low) when a memory cell connected to the bit lines is accessed (e.g., during a read or write operation).

At 1204, the TMC 320 determines a compensation scheme (e.g., voltage compensation or dynamic MEMACC compensation) to implement to compensate for the timing margin error detected at 1202. In some aspects, the selected compensation scheme may be stored in a configuration register. In such aspects, the TMC 320 may read the configuration register to obtain the selected compensation scheme. At 1206, the TMC 320 may determine if the compensation scheme is dynamic MEMACC compensation. For instance, the TMC 320 may determine the compensation scheme is dynamic MEMACC compensation if a value stored in the configuration register indicates the selected compensation scheme is dynamic MEMACC compensation. If the TMC 320 determines dynamic MEMACC is not selected, the TMC 320 may determine, at 1216 if voltage compensation is selected. Otherwise, the TMC 320 may continue to 1208.

At 1208, the TMC 320 may, as part of implementing dynamic MEMACC compensation, obtain voltage and frequency settings based on a current PSTATE of the CPU in which the memory is implemented. For instance, the TMC 320 may obtain the voltage and frequency settings from a core-PSTATE finite state machine 1230.

At 1210, the TMC 320 may read MEMACC configuration values (e.g., memory access time) for the memory based on the current PSTATE of the CPU. More specifically, the TMC 320 may read the configuration values from fuses 1232 programmed with the configuration values for the memory.

At 1212, the TMC 320 may provide (e.g., drive) adjustments to the current memory access timing settings of the memory based on the configuration values obtained at 1210. For instance, the TMC 320 may provide the adjustments to the memory access timing settings to a dynamic MEMACC controller 1234.

At 1214, the TMC 320 may determine whether the timing margin error (or imminence of the error) is still present after providing (e.g., driving) the adjustments to the current memory access timing settings. If the timing margin error is no longer present, the TMC 320 may revert to 1212 and decrease the previous adjustments to the memory access timing settings. Assuming the timing margin error is still no longer present after decreasing the previous adjustments to the memory access timing settings, the TMC 320 may again revert to 1212 and further decrease the most recent adjustments to the memory access timing settings. This process may be performed iteratively until the timing margin error is once again detected. In this manner, the process of dynamically adjusting the memory access timing settings of the memory may determine the minimum amount of adjustments needed to the memory access timing settings to compensate for the timing margin error.

In response to determining at 1216 that the voltage compensation scheme is selected, the TMC 320 may, at 1218, obtain the target voltage values (e.g., maximum voltage values) for a power supply rail 1236 of the memory given the current PSTATE of the CPU. For example, the TMC 320 may access the fuses 1232 programmed with the target voltage values for the power supply rail of the memory given the current PSTATE of the CPU.

At 1220, the TMC 320 may interact with a voltage regulator to increase a voltage at the power supply rail 1236 to the target voltage value.

At 1222, the TMC 320 may determine whether the timing margin error (or imminence of the error) is still present after increasing the voltage at the power supply rail 1236 to the target voltage value. If the timing margin error is no longer present, the TMC 320 may revert to 1220 and interact with the voltage regulator to decrease the voltage at the power supply rail 1236. Assuming the timing margin error is still no longer present after decreasing the previous adjustments to the memory access timing settings, the TMC 320 may again revert to 1220 and further decrease the voltage at the power supply rail 1236. This process may be performed iteratively until the timing margin error is once again detected. In this manner, the process of dynamically adjusting the voltage at the power supply rail 1236 may determine the minimum amount by which the voltage at the power supply rail 1236 needs to be increased to compensate for the timing margin error.

### Example Method for Detecting Aging of Local Memory in a CPU and Compensating for The Aging of the Local Memory

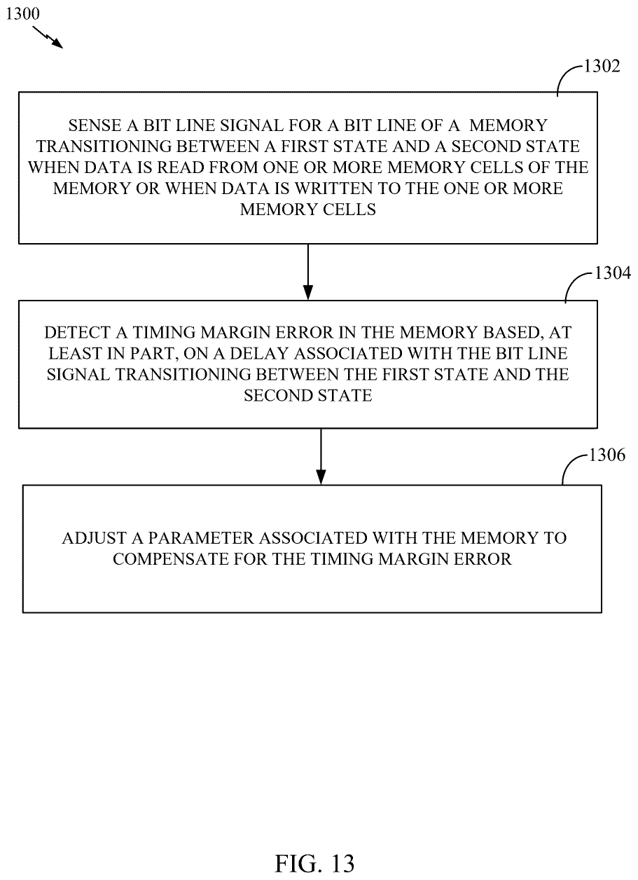

FIG. 13 depicts an example method 1300 for detecting aging of local memory in a CPU according to some aspects of the present disclosure. For example, the method 1300 may be performed by the system 300 of FIG. 3. Furthermore, although FIG. 13 depicts steps performed in a particular order for purposes of illustration and discussion, the method 1300 discussed herein is not intended to be limited to any particular order or arrangement. One skilled in the art, using the disclosure provided herein, will appreciate that various steps of the method 1300 can be omitted, rearranged, combined and/or adapted in various ways without deviating from the scope of the present disclosure.

At 1302, the method 1300 includes sensing a bit line signal for a bit line of the local memory in the CPU transitioning between a first state and a second state when data is read from one or more memory cells of the local memory or when data is written to the one or more memory cells of the local memory.

At 1304, the method 1300 includes detecting a timing margin error in the local memory based, at least in part, on a delay associated with the bit line signal transitioning between the first state and the second state.

At 1306, the method 1300 includes adjusting a parameter associated with the local memory to compensate for the timing margin error.

### Example Processing System

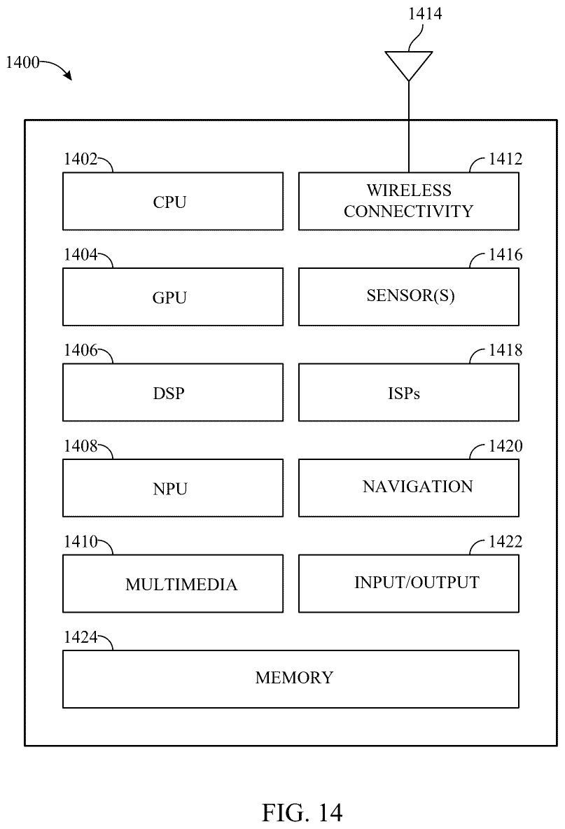

In some aspects, the system 300 depicted in FIG. 3 may be implemented in a processing system. FIG. 14 depicts an example processing system 1400. Although depicted as a single system for conceptual clarity, in some aspects, as discussed above, the operations described below with respect to the processing system 1400 may be distributed across any number of devices or systems.

The processing system 1400 includes a central processing unit (CPU) 1402. Instructions executed at the CPU 1402 may be loaded, for example, from a memory 1424 associated with the CPU 1402.

The processing system 1400 also includes additional processing components tailored to specific functions, such as a graphics processing unit (GPU) 1404, a digital signal processor (DSP) 1406, a neural processing unit (NPU) 1408, a multimedia component 1410 (e.g., a multimedia processing unit), and a wireless connectivity component 1412.

An NPU, such as NPU 1408, is generally a specialized circuit configured for implementing the control and arithmetic logic for executing machine learning algorithms, such as algorithms for processing artificial neural networks (ANNs), deep neural networks (DNNs), random forests (RFs), and the like. An NPU may sometimes alternatively be referred to as a neural signal processor (NSP), tensor processing unit (TPU), neural network processor (NNP), intelligence processing unit (IPU), vision processing unit (VPU), or graph processing unit.

NPUs, such as the NPU 1408, are configured to accelerate the performance of common machine learning tasks, such as image classification, machine translation, object detection, and various other predictive models. In some examples, a plurality of NPUs may be instantiated on a single chip, such as a SoC, while in other examples the NPUs may be part of a dedicated neural-network accelerator.

NPUs may be optimized for training or inference, or in some cases configured to balance performance between both. For NPUs that are capable of performing both training and inference, the two tasks may still generally be performed independently.

NPUs designed to accelerate training are generally configured to accelerate the optimization of new models, which is a highly compute-intensive operation that involves inputting an existing dataset (often labeled or tagged), iterating over the dataset, and then adjusting model parameters, such as weights and biases, in order to improve model performance. Generally, optimizing based on a wrong prediction involves propagating back through the layers of the model and determining gradients to reduce the prediction error.

NPUs designed to accelerate inference are generally configured to operate on complete models. Such NPUs may thus be configured to input a new piece of data and rapidly process this piece of data through an already trained model to generate a model output (e.g., an inference).

In some implementations, the NPU 1408 is a part of one or more of the CPU 1402, the GPU 1404, and/or the DSP 1406.

In some examples, the wireless connectivity component 1412 may include subcomponents, for example, for third generation (3G) connectivity, fourth generation (4G) connectivity (e.g., 4G Long-Term Evolution (LTE)), fifth generation connectivity (e.g., 5G or New Radio (NR)), Wi-Fi connectivity, Bluetooth connectivity, and/or other wireless data transmission standards. The wireless connectivity component 1412 is further coupled to one or more antennas 1414.

The processing system 1400 may also include one or more sensor processing units 1416 associated with any manner of sensor, one or more image signal processors (ISPs) 1418 associated with any manner of image sensor, and/or a navigation processor 1420, which may include satellite-based positioning system components (e.g., GPS or GLONASS), as well as inertial positioning system components.

The processing system 1400 may also include one or more input and/or output devices 1422, such as screens, touch-sensitive surfaces (including touch-sensitive displays), physical buttons, speakers, microphones, and the like.

The processing system 1400 also includes the memory 1424, which is representative of one or more static and/or dynamic memories, such as a dynamic random access memory, a flash-based static memory, and the like. In this example, the memory 1424 includes computer-executable components, which may be executed by one or more of the aforementioned processors of the processing system 1400.

Generally, the processing system 1400 and/or components thereof may be configured to perform the methods described herein.

Notably, in other aspects, elements of the processing system 1400 may be omitted, such as where the processing system 1400 is a server computer or the like. For example, the multimedia component 1410, the wireless connectivity component 1412, the sensor processing units 1416, the ISPs 1418, and/or the navigation processor 1420 may be omitted in other aspects. Further, aspects of the processing system 1400 may be distributed between multiple devices.

### Example Clauses

In addition to the various aspects described above, specific combinations of aspects are within the scope of the disclosure, some of which are detailed below:

Aspect 1: A method for operating a memory, the method comprising: sensing a bit line signal for a bit line of the memory transitioning between a first state and a second state when data is read from one or more memory cells of the local memory or when data is written to the one or more memory cells of the memory; detecting a timing margin error in the memory based, at least in part, on a delay associated with the bit line signal transitioning between the first state and the second state; and adjusting a parameter associated with the memory to compensate for the timing margin error.

Aspect 2: The method of Aspect 1, wherein the detecting comprises: generating a pulse signal having a pulse width that is proportional to the delay associated with the bit line signal transitioning between the first state and the second state; converting the pulse signal to a sensed voltage based, at least in part, on the pulse width; comparing the sensed voltage to a reference voltage that is lower than a supply voltage for the local memory; and predicting the timing margin error based on the comparing indicating the sensed voltage is greater than the reference voltage.

Aspect 3: The method of Aspect 2, wherein the sensing comprises: adjusting a sensitivity of a sensor configured to generate the pulse signal, the sensitivity of the sensor adjusted based on one or more operating conditions for the local memory; and sensing, using the adjusted sensor, the bit line signal transitioning between the first state and the second state.

Aspect 4: The method of Aspects 2 or 3, further comprising: configuring a finite state machine in a first state of a plurality of different states in response to generating the pulse signal, wherein the comparing occurs in response to configuring the finite state machine in the first state.

Aspect 5: The method of any of Aspects 2 to 4, wherein converting the pulse signal to the sensed voltage comprises charging a capacitor to a voltage level that is proportional to the pulse width.

Aspect 6: The method of any of Aspects 1 to 5, wherein adjusting a parameter to compensate for the timing margin error comprises: determining a current power mode for the memory, the current power mode corresponding to one of a plurality of different power modes in which the memory is configurable; and increasing a voltage at a memory rail of the memory from a first voltage to a second voltage based on the current power mode for the memory.

Aspect 7: The method of Aspect 6, further comprising: determining whether the timing margin error is still detected in the memory, in response to increasing the voltage; and decreasing the voltage at the memory rail from the second voltage to a third voltage that is greater than the first voltage, in response to determining the timing margin error is no longer detected in the memory.

Aspect 8: The method of any of Aspects 1 to 5, wherein adjusting a parameter to compensate for the timing margin error comprises: determining a current power mode for the memory, the current power mode corresponding to one of a plurality of power modes in which the memory is configurable; obtaining memory access timing settings for the memory based on the current power mode for the memory; and adjusting a memory access timing setting for the memory from a first memory access timing setting of the memory access settings in which memory accesses occur at a first speed to a second memory access timing setting of the memory access timing settings in which memory accesses occur at a second speed that is slower than the first speed.

Aspect 9: The method of Aspect 8, further comprising: determining whether the timing margin error is still detected in the memory, in response to adjusting the memory access timing setting for the local memory from the first memory access timing setting to the second memory access timing setting; and adjusting the memory access timing setting for the memory from the second memory access timing setting to a third memory access timing setting of the memory access timing settings in which memory accesses occur at a third speed that is faster than the second speed, in response to determining the timing margin error is no longer detected in the memory.

Aspect 10: A timing margin monitor for detecting timing margin errors in a memory array, the timing margin monitor comprising: a transition detector having an input coupled to a bit line of the memory array, the transition detector configured to output a pulse signal having a width corresponding to a delay associated with a bit line signal on the bit line transitioning between a first logic state and a second logic state; a pulse detector configured to generate a sensed voltage signal based on the pulse signal, the sensed voltage signal having a voltage value corresponding to the width of the pulse signal; and a comparator configured to determine whether a timing margin error exists in the memory array based on the sensed voltage signal and a reference voltage signal.

Aspect 11: The timing margin monitor of Aspect 10, wherein the transition detector comprises: a first chain of inverters coupled to the input; a second chain of inverters coupled to the input; and an exclusive or (XOR) gate having a first input and a second input, the first input coupled to an output of the first chain of inverters, the second input coupled to an output of the second chain of inverters.

Aspect 12: The timing margin monitor of Aspect 11, wherein the transition detector further comprises: a not or (NOR) gate having a first input coupled to an output of the XOR gate, the NOR gate having a second input coupled to an output of a sense amplifier connected to the bit line; and an inverter having an input coupled to an output of the NOR gate, the inverter configured to output the pulse signal.

Aspect 13: The timing margin monitor of any of Aspects 10 to 12, wherein the comparator is configured to output a timing margin error signal when a sensed voltage indicated by the sensed voltage signal is greater than a reference voltage indicated by the reference voltage signal.

Aspect 14: The timing margin monitor of Aspect 13, wherein an output of the comparator is coupled to a timing margin controller included in a controller for the memory array, wherein the timing margin controller is configured to implement a dynamic compensation scheme to compensate for the timing margin error indicated by the timing margin error signal.

Aspect 15: The timing margin monitor of any of Aspects 10 to 14, further comprising: a finite state machine (FSM) controller configured to transition from a first state to a second state upon receiving an interrupt signal from the transition detector.

Aspect 16: The timing margin monitor of Aspect 15, wherein in the second state, the FSM controller is configured to output a control signal to activate the comparator to determine whether the timing margin error exists in the memory array.

Aspect 17: The timing margin monitor of Aspect 15, wherein the transition detector is configured to generate the interrupt signal to indicate to the FSM controller that the transition detector detected a pulse.

Aspect 18: The timing margin monitor of any of Aspects 10 to 17, wherein a reference voltage indicated by the reference voltage signal is less than a supply voltage for the memory array.

Aspect 19: The timing margin monitor of any of Aspects 10 to 18, wherein the pulse detector is configurable in a plurality of different sensitivity settings associated with detecting the timing margin error.

Aspect 20: An apparatus comprising: means for sensing a bit line signal for a bit line of a local memory in a CPU transitioning between a first state and a second state when data is read from one or more memory cells of the local memory or when data is written to the one or more memory cells of the local memory; means for detecting a timing margin error in the local memory based, at least in part, on a delay associated with the bit line signal transitioning between the first state and the second state; and means for adjusting a parameter associated with the local memory to compensate for the timing margin error.

### ADDITIONAL CONSIDERATIONS

The various operations of methods described above may be performed by any suitable means capable of performing the corresponding functions. The means may include various hardware and/or software components(s) module(s), including, but not limited to a circuit or processor. Generally, where there are operations illustrated in figures, those operations may have corresponding counterpart means-plus-function components with similar numbering.

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the generic principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method for operating a memory array, comprising:
sensing a bit line signal for a bit line of the memory array transitioning between a first state and a second state when a memory cell of the memory array that is connected to the bit line is access during a memory operation;
detecting a timing margin error in the memory array based, at least in part, on a delay associated with the bit line signal transitioning between the first state and the second state exceeding a threshold; and
in response to detecting the timing margin error:
adjusting a voltage at a power supply rail for the memory array to compensate for the timing margin error; or
adjusting a memory access timing setting for the memory array to compensate for the timing margin error.

2. The method of claim 1, wherein the detecting comprises:
generating a pulse signal having a pulse width that is proportional to the delay associated with the bit line signal transitioning between the first state and the second state;
converting the pulse signal to a sensed voltage based, at least in part, on the pulse width;
comparing the sensed voltage to a reference voltage that is lower than a supply voltage for the memory array; and
predicting the timing margin error based on the comparing indicating the sensed voltage is greater than the reference voltage.

3. The method of claim 2, wherein the sensing comprises:
adjusting a sensitivity of a sensor configured to generate the pulse signal, the sensitivity of the sensor adjusted based on one or more operating conditions for the memory array; and
subsequent to adjusting the sensitivity of the sensor, sensing, using the sensor, the bit line signal transitioning between the first state and the second state.

4. The method of claim 2, further comprising:
configuring a finite state machine in a first state of a plurality of different states in response to generating the pulse signal, wherein the comparing occurs in response to configuring the finite state machine in the first state.

5. The method of claim 2, wherein converting the pulse signal to the sensed voltage comprises charging a capacitor to a voltage level that is proportional to the pulse width.

6. The method of claim 1, wherein the adjusting comprises adjusting the voltage at the power supply rail for the memory array, and wherein adjusting the voltage comprises:
determining a current power mode for the memory array, the current power mode corresponding to one of a plurality of different power modes in which the memory array is configurable; and
increasing the voltage at the power supply rail from a first voltage to a second voltage based on the current power mode for the memory array.

7. The method of claim 6, further comprising:
determining whether the timing margin error is still detected in the memory array after increasing the voltage at the power supply rail from the first voltage to the second voltage; and
in response to determining the timing margin error is no longer detected in the memory array, decreasing the voltage at the power supply rail from the second voltage to a third voltage that is greater than the first voltage.

8. The method of claim 1, wherein the adjusting comprises adjusting the memory access timing setting for the memory array, and wherein adjusting the memory access timing setting comprises:
determining a current power mode for the memory array, the current power mode corresponding to one of a plurality of power modes in which the memory array is configurable;
obtaining memory access timing settings for the memory array based on the current power mode; and
adjusting a memory access timing setting for the memory array from a first memory access timing setting of the memory access timing settings in which memory accesses occur at a first speed to a second memory access timing setting of the memory access timing settings in which memory accesses occur at a second speed that is slower than the first speed.

9. The method of claim 8, further comprising:
in response to adjusting the memory access timing setting for the memory from the first memory access timing setting to the second memory access timing setting, determining whether the timing margin error is still detected in the memory; and
in response to determining the timing margin error is no longer detected in the memory, adjusting the memory access timing setting for the memory array from the second memory access timing setting to a third memory access timing setting of the memory access timing settings in which memory accesses occur at a third speed that is faster than the second speed.

10. A timing margin monitor for detecting timing margin errors in a memory array, the timing margin monitor comprising:
a transition detector configured to generate a pulse signal indicative of a delay associated with a bit line signal on a bit line of the memory array transitioning between a first logic state and a second logic state;
a pulse detector configured to generate a sensed voltage signal based on the pulse signal; and
a comparator configured to determine whether a timing margin error exists in the memory array based on the sensed voltage signal and a reference voltage signal.

11. The timing margin monitor of claim 10, wherein the transition detector comprises:
an input coupled to the bit line;
a first chain of inverters coupled to the input;
a second chain of inverters coupled to the input; and
an exclusive or (XOR) gate having a first input and a second input, the first input coupled to an output of the first chain of inverters, the second input coupled to an output of the second chain of inverters.

12. The timing margin monitor of claim 11, wherein the transition detector further comprises:
a not or (NOR) gate having a first input coupled to an output of the XOR gate, the NOR gate having a second input coupled to an output of a sense amplifier connected to the bit line; and
an inverter having an input coupled to an output of the NOR gate, the inverter configured to output the pulse signal.

13. The timing margin monitor of claim 10, wherein the comparator is configured to output a timing margin error signal when a sensed voltage indicated by the sensed voltage signal is greater than a reference voltage indicated by the reference voltage signal.

14. The timing margin monitor of claim 13, wherein an output of the comparator is coupled to a timing margin controller included in a controller for the memory array, wherein the timing margin controller is configured to implement a dynamic compensation scheme to compensate for the timing margin error indicated by the timing margin error signal.

15. The timing margin monitor of claim 10, further comprising:
a finite state machine (FSM) controller configured to transition from a first state to a second state upon receiving an interrupt signal from the transition detector.

16. The timing margin monitor of claim 15, wherein in the second state, the FSM controller is configured to output a control signal to activate the comparator to determine whether the timing margin error exists in the memory array.

17. The timing margin monitor of claim 15, wherein the transition detector is configured to generate the interrupt signal to indicate to the FSM controller that the transition detector detected a pulse.

18. The timing margin monitor of claim 10, wherein a reference voltage indicated by the reference voltage signal is less than a supply voltage for the memory array.

19. The timing margin monitor of claim 10, wherein the pulse detector is configurable in a plurality of different sensitivity settings associated with detecting the timing margin error.

20. An apparatus comprising:
a memory array comprising a plurality of memory cells arranged in a plurality of columns, the memory array further comprising a plurality of bit lines, each respective bit line connected to a respective column of memory cells; and
a system configured to monitor the memory array for a timing margin error and automatically adjust operation of the memory array to compensate for the timing margin error, the system configured to:
sense a bit line signal for a respective bit line of the memory array transitioning between a first state and a second state when a respective memory cell of the plurality of memory cells that is connected to the respective bit line is accessed during a write operation;
detect the timing margin error in the memory array based, at least in part, on a delay associated with the bit line signal transitioning between the first state and the second state exceeding a threshold; and
in response to detecting the timing margin error:
adjust a voltage at a power supply rail for the memory array to compensate for the timing margin error; or
adjust a memory access timing setting for the memory array to compensate for the timing margin error.
